(19) United States
(12) Patent Application Publication
(10) Pub. No.: US 2006/0027899 A1
(43) Pub. Date: Feb. 9, 2006

(54) Structure with spherical contact pins

(75) Inventors: Giles Humpston, San Jose, CA (US); Masud Beroz, Livermore, CA (US); David B. Tuckerman, Orinda, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/166,861

(22) Filed: Jun. 24, 2005

Related U.S. Application Data
(60) Provisional application No. 60/583,108, filed on Jun. 25, 2004.

(51) Int. Cl. H01L 23/495

(52) U.S. Cl. 257/668

(57) ABSTRACT

A microelectronic package includes a microelectronic element having faces and contacts, and a flexible substrate spaced from and overlying a first face of the microelectronic element, the flexible substrate having conductive pads facing away from the first face of the microelectronic element. The package includes a plurality of spheres attached to the conductive pads of the flexible substrate and projecting away from the first face of the microelectronic element, each sphere having a contact surface remote from the conductive pads, the contact surfaces of the spheres including a contact metal devoid of solder. The package also includes a plurality of support elements disposed between the microelectronic element and the substrate for supporting the flexible substrate over the microelectronic element, the spheres being offset from the support elements.

### CROSS-REFERENCE TO RELATED APPLICATIONS

The present application claims benefit of U.S. Provisional Application Ser. No. 60/583,108, filed Jun. 25, 2004, the disclosure of which is hereby incorporated by reference herein.

### FIELD OF THE INVENTION

The present invention generally relates to microelectronic packages and more specifically to methods of making and testing microelectronic packages.

### BACKGROUND OF THE INVENTION

Microelectronic devices such as semiconductor chips typically require many input and output connections to other electronic components. The input and output contacts of a semiconductor chip or other comparable device are generally disposed in grid-like patterns that substantially cover a surface of the device (commonly referred to as an “area array”) or in elongated rows which may extend parallel to and adjacent each edge of the device's front surface, or in the center of the front surface. Typically, devices such as chips must be physically mounted on a substrate such as a printed circuit board, and the contacts of the device must be electrically connected to electrically conductive features of the circuit board.

Semiconductor chips are commonly provided in packages, which facilitate handling of the chip during manufacture and during mounting of the chip on an external substrate such as a circuit board or other circuit panel. For example, many semiconductor chips are provided in packages suitable for surface mounting. Numerous packages of this general type have been proposed for various applications. Most commonly, such packages include a dielectric element, commonly referred to as a “chip carrier” with terminals formed as plated or etched metallic structures on the dielectric. These terminals typically are connected to the contacts of the chip itself by features such as thin traces extending along the chip carrier features such as thin traces extending along the chip carrier itself and by fine leads or wires extending between the contacts of the chip and the terminals or traces. In the surface mounting operation, the package is placed onto a circuit board so that each terminal on the package is aligned with a corresponding contact pad on the circuit board. Solder or other bonding material is provided between the terminals and the contact pads. The package can be permanently bonded in place by heating the assembly so as to melt or “reflow” the solder or otherwise activate the bonding material.

Many packages include solder masses in the form of solder balls, typically about 0.1 mm to about 0.8 mm (5 and 30 mils) in diameter, attached to the terminals of the package. A package having an array of solder balls projecting from its bottom surface is commonly referred to as a ball grid array or “BGA” package. Other packages, referred to as land grid array or “LGA” packages are secured to the substrate by thin layers or lands formed from solder. Packages of this type can be quite compact. Certain packages, commonly referred to as “chip scale packages” occupy an area of the circuit board equal to, or only slightly larger than, the area of the device incorporated in the package. This is advantageous in that it reduces the overall size of the assembly and permits the use of short interconnections between various devices on the substrate, which in turn limits signal propagation time between devices and thus facilitates operation of the assembly at high speeds.

Assemblies including packages can suffer from stresses imposed by differential thermal expansion and contraction of the device and the substrate. During operation, as well as during manufacture, a semiconductor chip tends to expand and contract by an amount different from the amount of expansion and contraction of a circuit board. Where the terminals of the package are fixed relative to the chip or other device, these effects tend to cause the terminals to move relative to the contact pads on the circuit board. This can impose stresses in the solder, which connects the terminals to the substrates. As disclosed in certain preferred embodiments of U.S. Pat. Nos. 5,679,977; 5,148,266; 5,148,265; 5,455,390; and 5,518,964, the disclosures of which are incorporated by reference herein, semiconductor chip packages can have terminals which are movable with respect to the chip or other device incorporated in the package. Such movement can compensate to an appreciable degree for differential expansion and contraction.

Testing of packaged devices poses another formidable problem. In some manufacturing processes, it is necessary to make temporary connections between the terminals of the packaged device and a test fixture, and operate the device through these connections to assure that the device is fully functional. Ordinarily, these temporary connections must be made without bonding the terminals of the package to the test fixture. It is important to assure that all of the terminals are reliably connected to the conductive elements of the test fixture. However, it is difficult to make connections by pressing the package against a simple test fixture such as an ordinary circuit board having planar pads. If the terminals of the package are not coplanar, or if the conductive elements of the test fixture are not coplanar, some of the terminals will not contact their respective contact pads on the test fixture. For example, in a BGA package, differences in diameter of the solder balls attached to the terminals, and non-planarity of the chip carrier, may cause some of the solder balls to lie at different heights.

These problems can be alleviated through the use of specially constructed test fixtures having features arranged to compensate for non-planarity. However, such features add to the cost of the test fixture and, in some cases, introduce some unreliability into the test fixture itself. This is particularly undesirable because the test fixture, and the engagement of the device with the test fixture, should be more reliable than the packaged devices themselves in order to provide a meaningful test. Moreover, devices intended for high-frequency operation typically must be tested by applying high frequency signals. This requirement imposes constraints on the electrical characteristics of the signal paths in the test fixture, which further complicates construction of the test fixture.

Additionally, where the packaged device has solder balls on its terminals, solder tends to accumulate on those parts of the test fixture, which engage the solder balls. This can shorten the life of the test fixture and impair its reliability.

A variety of solutions have been put forth to deal with the aforementioned problems. Certain packages disclosed in the aforementioned patents have terminals that can move with respect to the microelectronic device. Such movement can compensate to some degree for non-planarity of the terminals during testing.

U.S. Pat. Nos. 5,196,726 and 5,214,308 both issued to Nishiguchi et al. disclose a BGA-type approach in which bump leads on the face of the chip are received in cup-like sockets on the substrate and bonded therein by a low-melting point material. U.S. Pat. No. 4,975,079 issued to Beaman et al. discloses a test socket for chips in which dome-shaped contacts on the test substrate are disposed within conical guides. The chip is forced against the substrate so that the solder balls enter the conical guides and engage the dome-shaped pins on the substrate. Sufficient force is applied so that the dome-shaped pins actually deform the solder balls of the chip.

A further example of a BGA socket may be found in commonly assigned U.S. Pat. No. 5,802,699, issued Sep. 8, 1998, the disclosure of which is hereby incorporated by reference herein. The '699 patent discloses a sheet-like connector having a plurality of holes. Each hole is provided with at least one resilient laminar contact extending inwardly over a hole. The bump leads of a BGA device are advanced into the holes so that the bump leads are engaged with the contacts. The assembly can be tested, and if found acceptable, the bump leads can be permanently bonded to the contacts.

Commonly assigned U.S. Pat. No. 6,202,297, issued Mar. 20, 2001, the disclosure of which is hereby incorporated by reference herein, discloses a connector for microelectronic devices having bump leads and methods for fabricating and using the connector. In one embodiment of the '297 patent, a dielectric substrate has a plurality of posts extending upwardly from a front surface. The posts may be arranged in an array of post groups, with each post group defining a gap therebetween. A generally laminar contact extends from the top of each post. In order to test a device, the bump leads of the device are each inserted within a respective gap thereby engaging the contacts which wipe against the bump lead as it continues to be inserted. Typically, distal portions of the contacts deflect downwardly toward the substrate and outwardly away from the center of the gap as the bump lead is inserted into a gap.

Commonly assigned U.S. Pat. No. 6,177,636, the disclosure of which is hereby incorporated by reference herein, discloses a method and apparatus for providing interconnections between a microelectronic device and a supporting substrate. In one preferred embodiment of the '636 patent, a method of fabricating an interconnection component for a microelectronic device includes providing a flexible chip carrier having first and second surfaces and coupling a conductive sheet to the first surface of the chip carrier. The conductive sheet is then selectively etched to produce a plurality of substantially rigid posts. A compliant layer is provided on the second surface of the support structure and a microelectronic device such as a semiconductor chip is engaged with the compliant layer so that the compliant layer lies between the microelectronic device and the chip carrier, and leaving the posts projecting from the exposed surface of the chip carrier. The posts are electrically connected to the microelectronic device. The posts form projecting package terminals, which can be engaged in a socket or solder-bonded to features of a substrate as, for example, a circuit panel. Because the posts are movable with respect to the microelectronic device, such a package substantially accommodates thermal coefficient of expansion mismatches between the device and a supporting substrate when the device is in use. Moreover, the tips of the posts can be coplanar or nearly coplanar.

There have been a number of advances related to providing microelectronic packages having pins or conductive posts that are movable relative to a microelectronic element. Certain preferred embodiments of commonly assigned U.S. patent application Ser. No. 10/959,465, filed Oct. 6, 2004, the disclosure of which is hereby incorporated by reference herein, disclose a microelectronic package including a microelectronic element having faces and contacts and a flexible substrate spaced from and overlying a first face of the microelectronic element. The package has a plurality of conductive posts extending from the flexible substrate and projecting away from the first face of the microelectronic element, with at least some of the conductive posts are electrically interconnected with the microelectronic element. The microelectronic package includes a plurality of support elements supporting the flexible substrate over the microelectronic element. The conductive posts are offset from the support elements to facilitate flexure of the substrate and movement of the posts relative to the microelectronic element.

Certain preferred embodiments of commonly assigned U.S. patent application Ser. No. 11/014,439, filed Dec. 16, 2004, [attorney docket No. Tessera 3.0-374], entitled “MICROELECTRONIC PACKAGES AND METHODS THEREFOR”, the disclosure of which is hereby incorporated by reference herein, disclose a support structure having a plurality of spaced apart support elements and a flexible sheet overlying the support elements. The conductive posts are offset in horizontal directions from the support elements. The offset between the posts and the support elements allows the posts, and particular the bases of the posts, to move independently of one another relative to a microelectronic element.

Certain preferred embodiments of commonly assigned U.S. patent application Ser. No. 10/985,126 (attorney docket no. Tessera 3.0-375], entitled “Micro Pin Grid Array With Wiping Action,” filed Nov. 10, 2004, disclose a microelectronic package including a mounting structure, a microelectronic element associated with the mounting structure, and a plurality of conductive posts physically connected to the mounting structure and electrically connected to the microelectronic element. The conductive posts project from the mounting structure in an upward direction, with at least one of the conductive posts being an offset post. Each offset post has a base connected to the mounting structure, and the base of each offset post defines a centroid. Each offset post also defines an upper extremity having a centroid, the centroid of the upper extremity being offset from the centroid of the base in a horizontal offset direction transverse to the upward direction. The mounting structure is adapted to permit tilting of each offset post about a horizontal axis so that the upper extremities may wipe across a contact pad of an opposing circuit board.

Certain preferred embodiments of commonly assigned U.S. patent application Ser. No. 10/985,119 [attorney docket no. Tessera 3.0-376], filed Nov. 10, 2004, entitled “Micro Pin Grid Array With Pin Motion Isolation,” disclose a microelectronic package including a microelectronic element having faces and contacts, a flexible substrate overlying and spaced from a first face of the microelectronic element, and a plurality of conductive terminals exposed at a surface of the flexible substrate. The conductive terminals are electrically interconnected with the microelectronic element and the flexible substrate includes a gap extending at least partially around at least one of the conductive terminals. In certain embodiments, the package includes a support layer, such as a compliant layer, disposed between the first face of the microelectronic element and the flexible substrate. In other embodiments, the support layer includes at least one opening that is at least partially aligned with one of the conductive terminals.

Certain preferred embodiments of U.S. patent application Ser. No. 11/140,312, filed May 27, 2005, entitled “MICROELECTRONIC PACKAGES AND METHODS THEREFOR,” the disclosure of which is hereby incorporated by reference herein, disclose a microelectronic package including a microelectronic element having faces, contacts and an outer perimeter, a flexible substrate overlying and spaced from a first face of the microelectronic element, and an outer region of the flexible substrate extending beyond the outer perimeter of the microelectronic element. The package includes a plurality of conductive posts exposed at a surface of the flexible substrate and being electrically interconnected with the microelectronic element, with at least one of the conductive posts being disposed in the outer region of the flexible substrate, and a compliant layer disposed between the first face of the microelectronic element and the flexible substrate, the compliant layer overlying the at least one of the conductive posts that is disposed in the outer region of the flexible substrate. The package includes a support element in contact with the microelectronic element and the compliant layer, whereby the support element overlies the outer region of the flexible substrate.

The above-mentioned '439, '126 and '119 applications disclose microelectronic packages that are sold under the trademark Socketstrate®. A Socketstrate® device is a structure applied to electronic die or wafers that provides mechanical compliance in three orthogonal directions and particularly facilitates testing of die one or more times prior to permanently attaching the structure to a printed circuit board. In certain preferred embodiments, the Socketstrate® structure includes a sheet or tape of a dielectric material that has on one face an array of conductive protrusions or conductive pins. The conductive pins are connected to a wiring trace on the tape and then to bond pads on the die by short lengths of wire, such as traces or wire bonds. The combination of the metal pins and the mechanical compliance of the polymeric material used for the dielectric sheet enables the die to be pressed against a printed circuit board, with each conductive pin registering to a matching conductive pad on the printed circuit board so that a continuous electrical path may be established between each conductive pad and conductive pin. Because the connection between the conductive pins and the printed circuit board is not permanent, release of the pressure permits the die to be removed and thereby tested several times and/or the printed circuit board to be reused more than once. Permanent attachment of the die to the printed circuit board can be accomplished using known methods such as reflow of solder, conductive organic materials such as anisotropically conductive film and thermo-compression bonding. Because the flexible dielectric tape material provides the structure with mechanical compliance and sits between the die and the printed circuit board, it is typically referred to as a “compliant interposer.”

Although the Socketstrate® structure provides a highly desirable package, there are one or more practical difficulties with its implementation. In particular, in the embodiment where the conductive pins are attached to the tape, and the die is subsequently mounted on and interconnected to a printed circuit board, tooling is required that has recesses to accommodate the height of the conductive pins and minimize the risk of mechanical damage to the pins. Such tooling must be customized for each design because it depends on the exact dimensions of each pin and the sites on the tape that are populated with pins. One solution is to first attach an interconnected die to the dielectric tape, while the tape is substantially flat. The pins can then be attached and electrically interconnected with the tape. Although the result of such a process may be simple to conceive of and draw, in reality the conductive posts need to be approximately 100 microns in diameter at the tip and about 100-500 microns high. Formation and manipulation of such tiny and high aspect ratio conductive pins typically requires highly specialized manufacturing tools and techniques. Such manufacturing tools and techniques may be expensive.

Despite all of the above-described advances in the art, there remains a need for microelectronic packages having terminals that can accommodate test boards having non-planar contact pads. There also remains a need for microelectronic packages that are able to form reliable electrical interconnections with a circuit board during testing and burn-in of the package. Thus, still further improvements in making and testing microelectronic packages would be desirable.

### SUMMARY OF THE INVENTION

The present invention seeks to obtain the advantages of using Socketstrate® structures with conductive pins, without requiring the additional tooling for supporting the pins during die attach. Thus, in certain preferred embodiments, the present invention uses spheres rather than conductive posts, because spheres have no orientation problems. Preferred sizes for the spheres may be between 50-4,000 microns. In still other preferred embodiments, the present invention uses hollow rings instead of spheres, as disclosed in commonly assigned U.S. Pat. No. 5,971,253, the disclosure of which is hereby incorporated by reference herein.

In certain preferred embodiments of the present invention, a microelectronic package includes a microelectronic element having faces and contacts, and a flexible substrate spaced from and overlying a first face of the microelectronic element, the flexible substrate having conductive pads facing away from the first face of the microelectronic element. The first face may be a front face of the microelectronic element and the contacts may be accessible at the front face. The contacts may be spaced from one another in a grid array over the front face of the microelectronic element. The contacts may be disposed in one or more rows extending along the front face of the microelectronic element. The microelectronic element may be operable to interchange signals at a frequency above about 300 MHz through at least some of said spheres.

The flexible substrate may include a dielectric sheet. In certain preferred embodiments, a compliant material may be disposed between the flexible substrate and the microelectronic element.

The package may also include a plurality of spheres attached to the conductive pads of the flexible substrate and projecting away from the first face of the microelectronic element, each sphere having a contact surface remote from the conductive pads, whereby the contact surfaces of the spheres include a contact metal devoid of solder. At least one of the spheres may include a dielectric core and an electrically conductive outer coating over the dielectric core.

The package may also include a plurality of support elements disposed between the microelectronic element and the substrate for supporting the flexible substrate over the microelectronic element, the spheres being offset from the support elements.

Each sphere may include a first sphere that is attached by the solder to one of the conductive pads and a second sphere connected with the first sphere by the solder, the second sphere including the contact surface devoid of the solder. The contact metal may include a contact metal patch of a noble metal supported by a less noble metal. The noble metal may be gold and the less noble metal may be nickel and/or copper. The second sphere is desirably only partially coated by the solder so that the contact surface of the second sphere is covered by a contact metal patch that overlies the solder.

Although the present invention is not limited by any particular theory of operations, it is believed that using spheres or hollow rings instead of conductive posts will facilitate the manufacture of a reliable, testable microelectronic package or wafer. As described above, making packages having conductive pins typically requires special tooling for accommodating the conductive pins. This is because the pins are typically attached to the flexible, dielectric substrate or tape before the chips are attached to the tape. Thus, the tape must be placed atop a substrate having recesses for receiving the pins. The present invention seeks to avoid the need for complex tooling, thereby simplifying the process, by placing the tape on a flat substrate for assembling the tape with a microelectronic element. After assembly of the microelectronic element to the tape, the conductive spheres or rings are attached to conductive pads on the tape for creating an electrical connection between the spheres/rings and the contacts of the microelectronic element.

The preferred method for attaching the spheres to the conductive pads is to use a solder technique. Unfortunately, the soldering step typically results is spheres that are completely coated in solder. As a result, it is difficult to test the package because the solder-coated spheres will not make reliable electrical interconnections with the lands on a test board. One reason why the solder-coated spheres will not function reliably is because the solder will oxidize rapidly. Thus, the present invention seeks to provide packages having spheres, whereby the contact surface of the spheres is not coated with solder, but is covered by a noble metal that will not oxidize as rapidly as solder.

The present invention provides various methods for attaching spheres to conductive pads of a microelectronic package, whereby the spheres have contact surfaces that are covered with noble metals and are devoid of solder. As used herein, the terms noble metal and contact metal are synonymous. As used herein, a noble metal is a metal or alloy, such as gold, that is highly resistant to oxidation and corrosion. Examples of noble metals include gold, silver, tantalum, platinum and palladium. Noble metals are different than base metals, which oxidize and corrode relatively easily. Examples of base metals include iron, nickel, copper, lead and zinc.

Noble metals are highly preferred for being used on the contact surfaces of the spheres because the packages can be readily and reliably tested by abutting the contact surfaces of the spheres against the lands of a test board. If the contact surfaces of the spheres were covered by the solder or the base metals that easily oxidize, then it would be more difficult to obtain an electrical interconnection between the spheres and the lands.

In the present invention, the spheres or rings can have a dielectric or non-conductive core and a conductive coating provided around the core. The contact surface portion of the sphere or ring is preferably covered with the noble or contact metal as described above. As a result, the portion of the sphere or core that contacts the land of the test board will not readily oxidize, insuring a reliable electrical interconnection between the microelectronic package or wafer and the test board.

In certain preferred embodiments, the sphere may include first spheres soldered to the conductive pads and second spheres attached to the first spheres by the solder. The stacked spheres form elongated conductive elements that provide many of the benefits that are found in conductive pins. In these particular embodiments, the first sphere is completely coated in solder, while the second sphere is only partially coated in solder, with the contact surface of the second sphere not being coated with solder. The contact surface of the second sphere is preferably a noble metal or coated with a noble metal.

In certain preferred embodiments, at least some of the support elements are electrically conductive, whereby at least one of the conductive support elements is electrically interconnecting at least one of the contacts of the microelectronic element with at least one of the spheres.

In certain preferred embodiments, the at least one sphere includes a plurality of spheres, and at least some of the spheres are connected to at least some of the contacts by conductive support elements immediately adjacent to the spheres. Conductive traces may be provided on the flexible substrate. The conductive traces may electrically interconnect at least some of the spheres with at least some of the conductive support elements.

In certain preferred embodiments, the flexible substrate has a bottom surface facing the front face of the microelectronic element and the conductive traces extend along the bottom surface of the flexible substrate. The flexible substrate may have a top surface facing away from the front face of the microelectronic element and the conductive traces extend along the top surface of the flexible substrate.

In certain preferred embodiments, the at least one of the conductive support elements may include a mass of a fusible material. In other preferred embodiments, the at least one of the conductive elements may include a dielectric core and an electrically conductive outer coating over the dielectric core.

In certain preferred embodiments, the support elements are disposed in an array so that the support elements define a plurality of zones of the flexible substrate, each of the zones being bounded by a plurality of the support elements defining corners of the zone, different ones of the spheres being disposed in different ones of the zones. In certain embodiments, only one of the spheres may be disposed in each of the zones.

In another preferred embodiment of the present invention, a microelectronic assembly includes a package as described above and a circuit panel having contact pads, whereby the contact surfaces of the spheres confront the contact pads and are electrically connected thereto. The assembly may include an electrically conductive bonding material securing the spheres to the contact pads.

In another preferred embodiment of the present invention, a microelectronic assembly includes a microelectronic element having faces and contacts, a flexible substrate spaced from and overlying a first face of the microelectronic element, and a plurality of conductive elements extending from the flexible substrate and projecting away from the first face of the microelectronic element, at least some of the conductive elements being electrically interconnected with the microelectronic element. The assembly also desirably includes a plurality of support elements disposed between the microelectronic element and the substrate for supporting the flexible substrate over the microelectronic element, at least some of the conductive elements being offset from the support elements, whereby each conductive element includes a first sphere and a second sphere connected with the first sphere. In certain preferred embodiments, the spheres may be replaced by the flexible bodies or rings disclosed in commonly assigned U.S. Pat. No. 5,971,253, the disclosure of which is hereby incorporated by reference herein.

In certain preferred embodiments, the first sphere is solder coated and the second sphere has a contact surface remote from the first sphere that is devoid of solder. The contact surface of the second sphere desirably includes a contact metal. The contact metal may include a noble metal, or a noble metal supported on a less noble metal. The noble metal may be gold and the less noble metal may be nickel or copper.

In yet another preferred embodiment of the present invention, a microelectronic package includes a microelectronic element having a front face with contacts, and a flexible substrate spaced from and overlying the microelectronic element, the flexible substrate having a first surface facing away from the microelectronic element and a second surface facing the microelectronic element, the flexible substrate being supported above the front face of the microelectronic element so that the substrate is at least partially unconstrained in flexure. The package may also include a plurality of conductive elements extending from the flexible substrate and projecting away from the microelectronic element, whereby the conductive elements are electrically connected to the microelectronic element. Each conductive element may include at least one sphere having a contact surface that is remote from the flexible substrate, whereby the contact surfaces are covered by a contact metal and are devoid of solder. Each conductive element may include a first solder coated sphere attached to a conductive pad on the flexible substrate and a second sphere attached to the first sphere, the second sphere including the contact surface covered by the contact metal.

In certain preferred embodiments, the spheres may have lines formed thereon that stop the spread of solder. When the spheres are positioned atop conductive pads of a package or wafer package and soldered to the pads, the stop lines are extending parallel to the face of the microelectonic elements so that the contact surfaces of the spheres are not covered with solder or other contaminants. As noted above, the contact surfaces are preferably covered with substantially non-oxidizing substances such as noble metals.

These and other preferred embodiments of the present invention will be described in more detail below.

### BRIEF DESCRIPTION OF THE DRAWINGS

FIGS. 1A-1D show a method of making a microelectronic assembly in accordance with certain preferred embodiments of the present invention.

FIG. 2 shows the microelectronic assembly of FIG. 1D having spheres attached thereto.

FIG. 3 shows the microelectronic assembly of FIG. 2 taken along line III-III thereof.

FIGS. 4A and 4B show the microelectronic assembly of FIG. 2 being tested, in accordance with certain preferred embodiments of the present invention.

FIGS. 5A and 5B show a method of attaching a sphere to a conductive pad of a microelectronic assembly, in accordance with certain preferred embodiments of the present invention.

FIG. 6 shows a sphere attached to a conductive pad of a microelectronic assembly, in accordance with another preferred embodiment of present invention.

FIGS. 7A and 7B show a method of attaching a layer of a contact metal to a contact surface of a sphere, in accordance with other preferred embodiments of the present invention.

FIG. 8 shows the assembly of FIG. 7B being connected with a printed circuit board, in accordance with certain preferred embodiments of the present invention.

FIGS. 9A-9D show a method of making and testing a microelectronic assembly, in accordance with further preferred embodiments of the present invention.

FIG. 10 shows a cross sectional view of a microelectronic assembly having stacked spheres, in accordance with further preferred embodiments of the present invention.

FIG. 11 shows a cross sectional view of a microelectronic assembly having stacked spheres, in accordance with yet further preferred embodiments of the present invention.

FIG. 12 shows the cross sectional view of a microelectronic assembly having stacked spheres, in accordance with yet further preferred embodiments of the present invention.

FIG. 13 shows a cross sectional view of a microelectronic assembly, in accordance with still further preferred embodiments of the present invention.

FIGS. 14A-14D show a method of securing spheres to a microelectronic element, in accordance with certain preferred embodiments of the present invention.

FIG. 15 shows a cross sectional view of a microelectronic assembly having spheres during a testing operation, in accordance with certain preferred embodiments of the present invention.

FIG. 16 shows a cross sectional view of the microelectronic assembly of FIG. 15 after being attached to a printed circuit board, in accordance with certain preferred embodiments of the present invention.

FIGS. 17A-17D show a method of securing spheres to a microelectronic element, in accordance with further preferred embodiments of the present invention.

FIGS. 18A and 18B show a method of securing spheres to a microelectronic assembly, in accordance with certain preferred embodiments of the present invention.

FIG. 19 shows a microelectronic assembly, in accordance with still further preferred embodiments of the present invention.

### DETAILED DESCRIPTION OF PREFERRED EMBODIMENTS

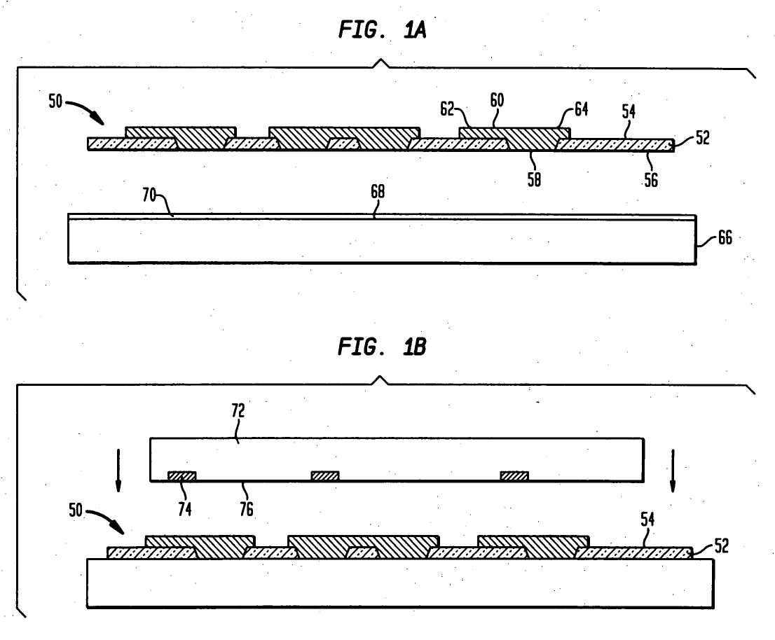

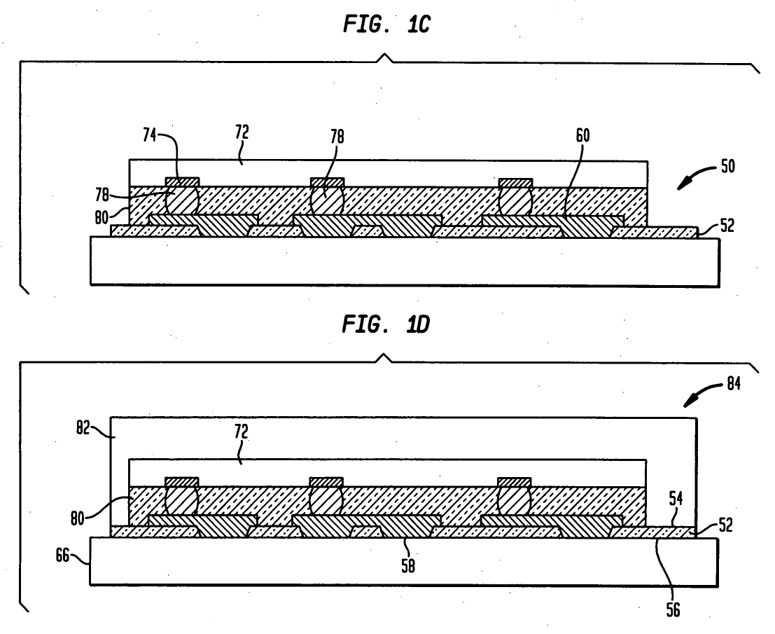

Referring to FIGS. 1A-1D, in accordance with certain preferred embodiments of the present invention, a connection component 50 includes a flexible, dielectric substrate 52 having a top surface 54 and a bottom surface 56. The connection component 50 includes a plurality of conductive pads 58 that are accessible at the second surface 56 of the dielectric substrate 52. The connection component 50 also includes conductive traces 60 having first ends 62 and second ends 64 connected with the conductive pads 58. The exposed surface of the conductive pads 58 and the second surface 56 of the dielectric substrate 52 are substantially coplanar. The conductive traces 60 extend over the first surface 54 of the flexible dielectric substrate 52.

The flexible dielectric substrate 52 may be made of a polyimide or other polymeric sheet. Although the thickness of the dielectric substrate 52 will vary with the application, the dielectric substrate most typically is about 10 μm-100 μm thick. In the particular embodiment illustrated in FIGS. 1A-1D, the conductive traces are disposed on top surface 54 of the flexible sheet 52. However, in other embodiments, the conductive traces 60 may extend on the top surface 54 of the flexible sheet 52; on both the top and bottom faces or within the interior of flexible substrate 52. Thus, as used in this disclosure, a statement that a first feature is disposed “on” a second feature should not be understood as requiring that the first feature lie on a surface of the second feature. Conductive traces 60 may be formed from any electrically conductive material, but most typically are formed from copper, copper alloys, gold or combinations of these materials. The thickness of the traces will also vary with the application, but typically is about 5 μm-25 μm.

In certain preferred embodiments, before or while assembling the connection component 50 with a microelectronic element such as a semiconductor chip, the connection component 50 is positioned atop a support layer 66 having a substantially flat surface 68. After the connection component has been placed atop the support structure 66, the top surface 68 of the support layer 66 desirably abuts against the conductive pads 58 and the second surface 56 of the dielectric substrate 52.

The support layer 66 may be attached to the connection component 50 either during or after fabrication of the connection component 50. An adhesive material 70, such as an adhesive layer having relatively low tackiness, may be provided over the top surface 68 of the support layer 66. The adhesive material preferably temporarily attaches the connection component 50 to the support layer 66 during fabrication of the microelectronic assembly.

Referring to FIG. 1B, a microelectronic element 72, such as a semiconductor chip, has contacts 74 accessible at a front face 76 thereof. The front face 76 of the microelectronic element 72 is juxtaposed with the first surface 54 of the flexible dielectric substrate 52 before assembling the elements together.

Referring to FIG. 1C, the assembly includes conductive support elements 78 that are disposed between the traces 60 of the connection component 50 and the chip contacts 74 for electrically interconnecting the microelectronic element 72 with the connection component 50. A layer of a compliant, dielectric encapsulant 80 may be disposed around the conductive support elements 78 and between the microelectronic element 72 and the flexible substrate 52.

Referring to FIG. 1D, in certain preferred embodiments, an overmold 82 is formed around the microelectronic assembly. The overmold 82 preferably covers the rear face and edges of the chip 72 and the top surface 54 of the flexible substrate 52. The overmold 82 preferably prevents contamination of the assembly and adds stability to the package. Although the present invention is not limited by any particular theory of operation, it is believed that the support layer 66 supports the flexible substrate 52 during assembly of the connection component 50 with the microelectronic element 72, and particularly when forming the electrical interconnection between the microelectronic element 72 and the connection component 50. The support layer 66 also preferably provides planarity for the components, such as when the compliant encapsulant 80 flows under the microelectronic element 72, so as to provide a thinner assembly. After the assembly has been completed, the support layer 66 may be removed or stripped away to expose the conductive pads 58 at the second surface 56 of the dielectric layer 52. The microelectronic package 84 may then be assembled with another element, such as a printed circuit board.

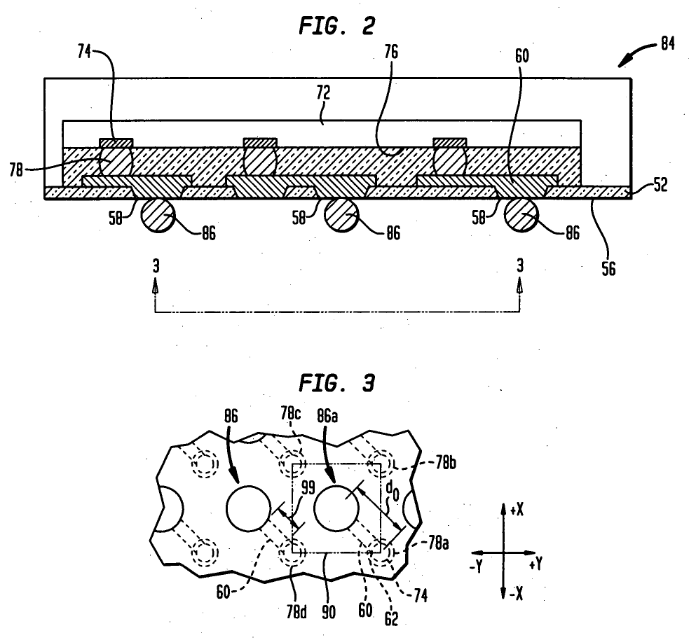

Referring to FIG. 2, conductive spheres 86 may be attached to and electrically interconnected with conductive pads 58 of the microelectronic package 84. The conductive spheres 86 may be hollow or solid, may be made of metals such as solder or copper, or may be made of a non-metal such as a glass or polymers. Because the spheres 86 are required to provide an electrically conductive path between the conductive pads 58 on the flexible substrate 52 and the contacts on a printed circuit board (not shown), any non-metallic spheres must be coated with a layer of a conductive material such copper, nickel or gold. The contact surfaces of the spheres 86, i.e., the portion of the spheres that will make contact with the lands of a test board, are preferably devoid of solder or contaminants and covered by a noble metal that will not readily oxidize. Although solder may cover a portion of the surface of the spheres, it preferably does not cover the contact surface portion of the spheres. As a result, the package can be reliably tested without first requiring the wiping or removal of oxides from the contact surfaces of the spheres.

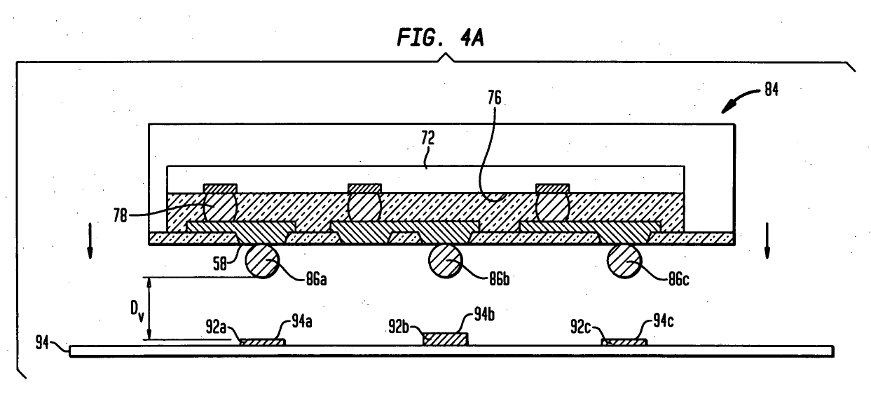

Referring to FIGS. 2 and 3, the microelectronic package 84 includes the conductive support elements 78, such as solder balls, in substantial alignment and electrically interconnected with contacts 74. As best seen in FIG. 3, contacts 74 and support elements 78 are disposed in an array which in this case is a rectilinear grid, having equally spaced columns extending in a first horizontal direction x and equally spaced rows extending in a second horizontal direction y orthogonal to the first horizontal direction. This structure is described in more detail in commonly assigned U.S. patent application Ser. No. 11/014,439, the disclosure of which is hereby incorporated by reference herein. Each contact 74 and support element 78 is disposed at an intersection of a row and a column, so that each set of four support elements 78 at adjacent intersections, such as support elements 78a, 78b, 78c and 78d, defines a generally rectangular, and preferably square, zone. The directions referred to in this disclosure are directions in the frame of reference of the components themselves, rather than in the normal gravitational frame of reference. Horizontal directions are directions parallel to the plane of the front surface of the chip, whereas vertical directions are perpendicular to that plane.

Referring to FIGS. 2 and 3, the electrically conductive spheres 86 project from the bottom surface 56 of flexible substrate 52. Each conductive sphere 86 is connected to the contact pad 58 accessible at the second surface of the substrate 52. The spheres 86 may be formed from any electrically conductive material, but desirably are formed from metallic materials such as lead, tin, nickel, copper, copper alloys, gold and combinations thereof. For example, the conductive spheres may be formed principally from tin and lead with a layer of gold at the contact surfaces of the spheres.

As best appreciated with reference to FIG. 3, the first ends 64 of the conductive traces 60 are disposed in a regular grid pattern corresponding to the grid pattern of the conductive support elements 78, whereas the conductive spheres 86 are disposed in a similar grid pattern. However, the grid pattern of the spheres 86 is offset in the first and second horizontal directions x and y from the grid pattern of the first ends 62 of the conductive traces 60 and the conductive support elements 78, so that each sphere 86 is offset in the −y and +x directions from the first end 62 of the trace 60 connected to that sphere 86.

The first end 62 of each trace 60 underlies a conductive support element 78 and is bonded to such support element, so that each sphere 86 is connected to one support element. In the embodiment illustrated, where the support elements are solder balls, the bonds can be made by providing the support elements on the contacts 74 of the chip 72 and positioning the flexible substrate 52, with the traces already formed thereon, over the support elements and reflowing the solder balls by heating the assembly. In a variant of this process, the solder balls can be provided on the first ends 62 of the traces. The process steps used to connect the first ends of the traces can be essentially the same used in flip-chip solder bonding of a chip to a circuit panel.

As mentioned above, the conductive spheres 86 are offset from the support elements 78 in the x and y horizontal directions. Unless otherwise specified herein, the offset distance do (FIG. 3) between a sphere 86 and a support element 78 can be taken as the distance between the center of area of the sphere 86 and the center of area of the support element 78. In the embodiment shown, where both the sphere 86 and the support element 78 have circular cross-sections, the centers of area lie at the geometric centers of these elements. Most preferably, the offset distance do is large enough that there is a gap 99 (FIG. 3) between adjacent edges of the sphere and the support element. Stated another way, there is a portion of the dielectric sheet 52 in the gap 99, which is not in contact with either the support element or the sphere.

Each conductive sphere 86 lies near the center of one zone 90 defined by four adjacent support elements 78, so that these support elements are disposed around the sphere. For example, support elements 78a-78d are disposed around sphere 86a. Each sphere 86 is electrically connected by a trace 60 and by one of these adjacent support elements 78 to the microelectronic device 72. The offset distances from a particular sphere to all of the support elements adjacent to that sphere may be equal or unequal to one another.

In the completed unit, the second surface 56 of the substrate 52 forms an exposed surface of the package, whereas conductive spheres 86 project from this exposed surface and provide terminals for connection to external elements. The flexible nature of the substrate 52 enables the spheres 86 to move relative to the contacts 74 on the chip 72.

The conductive support elements 78 create electrically conductive paths between the microelectronic element 72 and the flexible substrate 52 and traces 60. The conductive support elements 78 also space the flexible substrate 52 from the contact bearing face 76 of the microelectronic element 72. As further discussed below, this arrangement facilitates movement of the spheres 86.

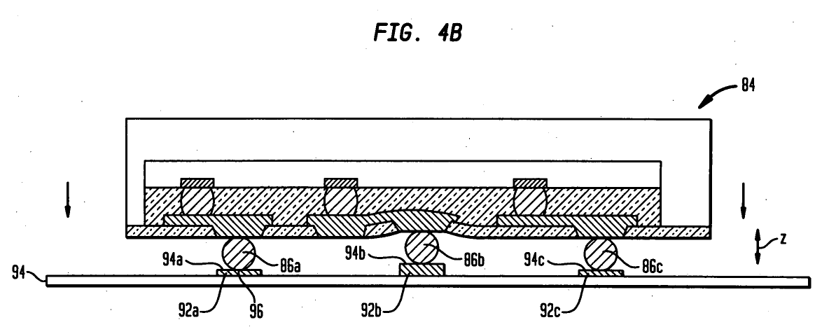

Referring to FIGS. 4A and 4B, in a method of operation according to a further embodiment of the invention, a microelectronic package 84 such as the package discussed above, is tested by juxtaposing the conductive spheres 86 with contact pads 92 on a second microelectronic element 94 such as a circuitized test board. The conductive spheres 86a-86c are placed in substantial alignment with top surfaces of the respective contact pads 92a-92c. As is evident in the drawing figure, the top surfaces 94a-94c of the respective contact pads 92a-92c are disposed at different heights and do not lie in the same plane. Such non-planarity can arise from causes such as warpage of the circuit board 94 itself and/or unequal thicknesses of the contact pads 92. Also, although not shown in FIG. 4A, the contact surfaces 96 of the spheres (i.e. the surface of the sphere that is remote from the conductive pad 58) may not be precisely coplanar with one another, due to factors such as unequal heights of support elements 78; non-planarity of the front surface 76 of the microelectronic element 72; warpage of the dielectric substrate 52; and unequal heights of the spheres 86 themselves. Also, the package 84 may be tilted slightly with respect to the circuit board 94. For these and other reasons, the vertical distances Dv between the contact surfaces 96 of the spheres 86 and the top surfaces 94 of the contact pads 92 may be unequal.

Referring to FIG. 4B, the microelectronic package 84 is moved toward the test board 94, by moving either the test board, the package or both. The contact surfaces 96 of the conductive spheres 86a-86c engage the respective contact pads 92a-92c and make electrical contact with the contact pads. The spheres are able to move so as to compensate for the initial differences in vertical spacing Dv (FIG. 4A), so that all of the spheres can be brought into contact with all of the contact pads simultaneously using only a moderate vertical force applied to urge the package and test board 94 together. In this process, at least some of the sphere contact surfaces are displaced in the vertical or z direction relative to other sphere contact surfaces.

A significant portion of this relative displacement arises from movement of the spheres relative to one another and relative to microelectronic element 72. Because the spheres are attached to flexible substrate 52 and are offset from the support elements 78, and because the support elements space the flexible substrate 52 from the front surface 76 of the microelectronic element 72, the flexible substrate can deform. Further, different portions of the substrate associated with different spheres can deform independently of one another. In practice, the deformation of the substrate may include bending and/or stretching of the substrate so that the motion of the sphere may include a tilting about an axis in the x-y or horizontal plane as well as some horizontal displacement of the sphere, and may also include other components of motion. For example, one portion of the flexible substrate 52 is reinforced by trace 60, and will tend to be stiffer than the other portions of the substrate 52. Also, a particular sphere may be positioned off-center in its region 90 (FIG. 3), so that the sphere lies closer to one support element, or to a pair of support elements, on one side of the sphere. For example, sphere 86a (FIG. 3) may be disposed closer to support elements 78a and 78b than to support elements 78c and 78d. The relatively small portion of the substrate between the sphere 86a and support elements 78a and 78b will be stiffer in bending than the relatively large portion of the substrate between the sphere 86a and support elements 78c and 78d. Such non-uniformities tend to promote non-uniform bending and hence tilting motion of the sphere. Tilting of the sphere tends to move the contact surfaces of the sphere toward the microelectronic element. The support elements 78 at the corners of the individual regions 90 substantially isolate the various regions from one another, so that the deformation of each region 90 is substantially independent of the deformation of other regions of the substrate 52.

The independent displacement of the spheres 86 relative to one another allows all of the contact surfaces 96 of the respective spheres 86 to contact all of the contact pads 92 on the test substrate 94. For example, the flexible substrate 52 in the vicinity of sphere 86b flexes substantially more than the flexible substrate in the vicinity of spheres 86a, 86c.

Because all of the contact surfaces 96 of the spheres 86 can be engaged reliably with all of the contact pads 92, the package can be tested reliably by applying test signals, power and ground potentials through the test circuit board 94 and through the engaged spheres and contact pads. Moreover, this reliable engagement is achieved with a simple test circuit board 94. For example, the contact pads 92 of the test circuit board 94 are simple, planar pads. The test circuit board need not incorporate special features to compensate for non-planarity or complex socket configurations. The test circuit board can be made using the techniques commonly employed to form ordinary circuit boards. This materially reduces the cost of the test circuit board, and also facilitates construction of the test circuit board with traces (not shown) in a simple layout compatible with high-frequency signals. Also, the test circuit board may incorporate electronic elements such as capacitors in close proximity to the contact pads as required for certain high-frequency signal processing circuits. Here again, because the test circuit board need not incorporate special features to accommodate non-planarity, placement of such electronic elements is simplified. In some cases, it is desirable to make the test circuit board as planar as practicable so as to reduce the non-planarity of the system and thus minimize the need for sphere movement. For example, where the test circuit board is highly planar a ceramic circuit board such as a polished alumina ceramic structure, only about 20 μm of sphere movement will suffice.

The internal features of package 84 are also compatible with high-frequency signals. The conductive support elements, traces and spheres provide low-impedance signal paths between the spheres and the contacts of the microelectronic element. Because each sphere is connected to an immediately adjacent conductive support element, traces 60 are quite short. The low-impedance signal paths are particularly useful in high-frequency operation, as, for example, where the microelectronic element must send or receive signals at a frequency of 300 MHz or more.

After testing, the microelectronic package may be removed from the test circuit board and permanently interconnected with another substrate such as a circuit panel having contact pads, such as by bonding the spheres to the contact pads of the circuit panel using a conductive bonding material such as a solder. The solder-bonding process may be performed using conventional equipment commonly used for surface-mounting microelectronic components.

The spheres preferably can move relative to the microelectronic element to at least some degree during service so as to relieve stresses arising from differential thermal expansion and contraction. As discussed above in connection with the testing step, the individual spheres can move relative to the microelectronic element and relative to the other spheres by flexure or other deformation of substrate 52. Such movement can appreciably relieve stresses in the solder bonds between the spheres and the contact pads, which would otherwise occur upon differential thermal expansion or contraction of the circuit board and microelectronic element. Moreover, the conductive support elements can deform to further relieve stresses. The assembly is highly resistant to thermal cycling stresses, and hence highly reliable in service.

The assembly is also compact. Some or all of the conductive spheres and contact pads are disposed in the area occupied by the microelectronic element, so that the area of the circuit board occupied by the assembly may be equal to, or only slightly larger than, the area of the microelectronic element itself, i.e., the area of the front surface of the microelectronic element.

Referring to FIG. 4A, one preferred method for attaching the conductive spheres 86 to the conductive pads 58 of the flexible substrate 52 involves soldering. It is well known to those skilled in the art that the surface tension forces associated with molten solders provides accurate and repeatable alignment between parts that is set when the solder solidifies. Moreover, the formation of mechanically strong solder joints depends on the ability to form large, smooth, fillets as these minimize the stress concentration when the joint is subject to mechanical stress. Attempting to secure the spheres by soldering, however, is incompatible with the metallization on the spheres that is necessary for making the temporary connections to the printed circuit board. Metals that provide desirable contact metallurgy, in particular low contact resistance and do not tarnish easily in air, such as gold, are highly wetable by molten solder. Consequently, if attached by soldering, the molten solder will spread over the entire exposed surface area of the gold-coated spheres. It may not be possible to solve this problem by restricting the volume of solder applied to the pad on the compliant interposer. In attempts to restrict the quantity of solder, the amount of solder needs to be so small that it cannot be applied as a paste. As a result, a thin film coating technique must be used, which is an expensive process. Moreover, thin solder coatings have an extremely short shelf life because the surface area-to-volume ratio is unfavorable and the mechanical properties of the joint tend to be poor.

There are a number of solutions to the above-described soldering problem. One solution is to create on each conductive sphere a non-wetable band that the solder cannot cross. Such solder stop methods and materials are well known, but there may be practical issues in attempting to create such a non-wetable band on each sphere and then place each sphere so that each band is essentially perpendicular to the z-axis of the structure.

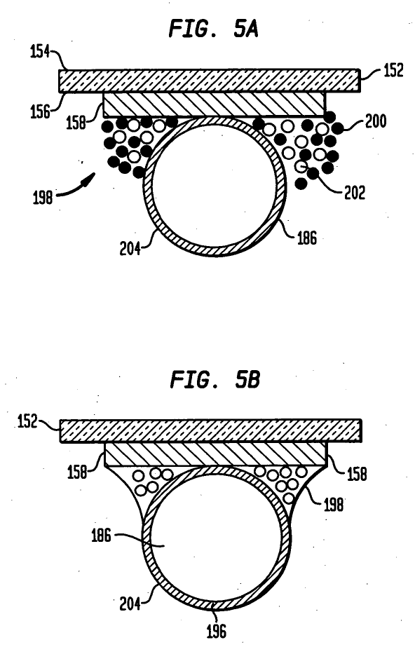

Referring to FIGS. 5A and 5B, in one preferred embodiment of the present invention, a package includes a compliant substrate 152 having a top surface 154 and a bottom surface 156 remote therefrom. The substrate has one or more conductive pads 158 accessible at the bottom surface 156 thereof. A mass of transient liquid phase solder 198 is provided on the one or more conductive pads 158. The transient liquid phase solder 198 comprises a solder paste 200 that is mixed with a high melting point metal 202. Copper and silver are common constituents. The high melting point metal is preferably provided in a powder form and is preferably made of a material that reacts strongly with solder. Before reflow of the transient liquid phase solder 198, a sphere 186 is abutted against the transient liquid phase solder 198 for holding the sphere 186 on the conductive pad 158. The sphere is a non-metal sphere coated with a layer of a contact metal 204. Referring to FIG. 5A, when the solder 198 is melted, the melted solder wets the sphere, the land, and the powder, but is constrained from flowing freely over the entire surface of the sphere by the high viscosity imparted by the powder. At the same time, the metallurgical reaction between the solder and the powder rapidly absorbs the free liquid so that the volume of solder available to spread is quickly eliminated. As a result, the solder is not able to cover the contact surface 196 of the sphere. Although the present invention is not limited by any particular theory of operation, it is believed that this method takes advantage of the self-aligning and mechanical benefits of solder joints, while the powder in the paste restricts spreading of the solder over the contact surface by virtue of surface tension and metallurgical reaction. As a result, the contact surface of the sphere will not readily oxidize, which facilitates reliable testing of the package.

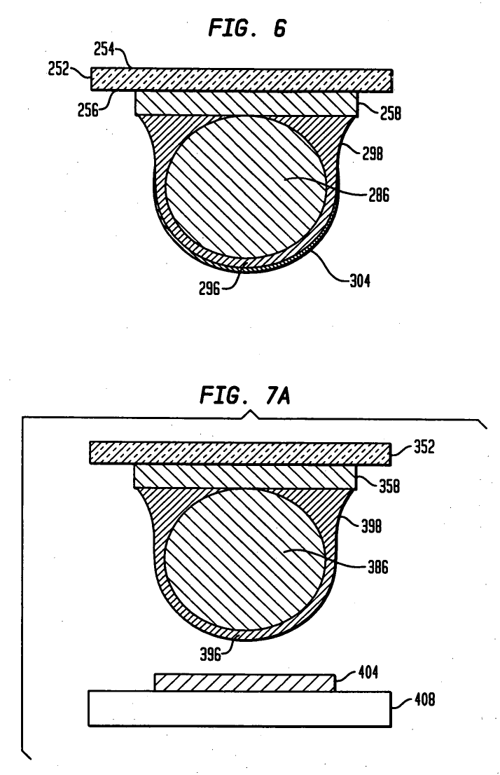

Referring to FIG. 6, another approach is to affix the spheres by soldering, taking advantage of the benefits of the surface tension afforded the molten solder and then recoating the surface of the spheres, particularly the exposed contact surface of the sphere with a desirable contact metallization, such as copper, then nickel, plus gold. In highly preferred embodiments, the outer layer of the contact metallization is a noble metal that does not readily oxidize. As shown in FIG. 6, a microelectronic assembly includes a flexible, dielectric substrate 252 having a first surface 254 and a second surface 256 remote therefrom. The microelectronic assembly includes one or more conductive pads 258 accessible at the second surface 256 of the flexible substrate 252. The conductive pads 258 of the flexible substrate 252 are electrically interconnected with a microelectronic element such as a semiconductor chip (not shown). A conductive sphere 286 is connected with the conductive pad 258 using solder 298. A layer of a contact metal 304 is applied over the solder present at the contact surface 296 of the sphere 286. The presence of the contact metal 304 facilitates testing of the microelectronic assembly when the conductive spheres are abutted against the lands of a test board or test socket.

The embodiment shown in FIG. 6 works effectively because it is easy to coat the entire surface of a sphere with a layer of solder having a consistent thickness. The contact metallization 304 need only be applied over the area 296 where the microelectronic assembly will contact the lands on a printed circuit board. As noted above, the contact metallization is preferably a noble metal or contact metal that does not readily oxidize.

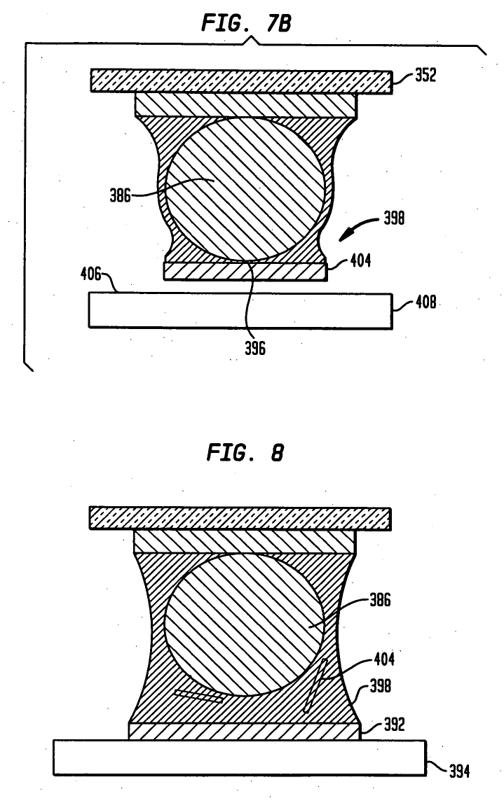

Referring to FIGS. 7A and 7B, in another preferred embodiment of the present invention, a microelectronic assembly includes a flexible, dielectric substrate 352 having conductive pads 358. Spheres 386 are affixed to the conductive pads 358 using solder 398, which takes advantage of the benefits of the surface tension afforded using molten solder. The exposed contact surface 396 of the sphere 386 is then coated with a layer of a desirable contact metal, such as a composite layer of copper, then nickel plus gold. This particular approach has some merit because it is relatively easy to coat the exposed surfaces 396 of the spheres 386 with a consistent thickness of solder. Such solder-coated spheres are sold commercially. As a result, there is no need to apply additional solder to either the spheres 386 or the conductive pads 358 to join the spheres 386 to the contact pads of the flexible substrate 352. Moreover, the volume of solder that is required to effectively join the sphere to the conductive pad is relatively small, and accurately controlled. After the spheres 386 have been joined with the conductive pads 358, the contact metal layer 404 need only be applied over the area 396 where the structure will mate with a printed circuit board. Thus, the contact metal layer 404 may be disposed by a line of sight technique, such as vapor deposition, or with less directional sensitivity, such as can be achieved by wet plating.

Referring to FIGS. 7A and 7B, after the sphere 386 is attached to and electrically interconnected with the conductive pad 358 using solder 398, and after the solder re-solidifies, the exposed contact surface 396 of the sphere 386 is over coated with the contact metal layer 404. The contact metal layer 404 may be provided as spaced pads provided over the top surface 406 of a sacrificial layer 408.

As shown in FIG. 7B, the spheres may be provided with a reliable contact metal layer 404 by coating the sacrificial substrate 408 with discrete islands of contact metals applied in reverse order, one matching the position of each sphere 386. For example, in one preferred embodiment, gold is adjacent to the sacrificial substrate 408 and copper is exposed to the atmosphere in the case of a copper/nickel/gold metallurgical sequence. Solder-coated spheres are first attached to the conductive pads of the complaint interposer, as described above. By positioning the solder-coated spheres in contact with the sacrificial substrate and conducting a reflow cycle, one pad of the contact metal 404 will become adhered to the contact face 396 of each sphere 386. Removal of the sacrificial substrate 408 leaves each sphere 386 with a patch of the desired contact metal 404 covering the area that will mate with the lands of a printed circuit board during testing. The sacrificial substrate can be removed by a number of different methods, including thermally, photons (ultraviolet), and chemical dissolution.

In order to attach the copper/nickel/gold metallurgical sequence to the sphere, the compliant interposer 352 is juxtaposed with the sacrificial layer 408 so that the spheres 386 are in contact with the islands of contact metal 404. Referring to FIG. 7B, the sphere 386 is pressed against the reverse-order contact metal island 404 and joined to it by reflow of the solder coating 398 on the sphere 386. The sacrificial substrate 408 may then be removed. The assembly may be tested by abutting the sphere with the attached layer of contact metal 404 against one or more contacts on a printed circuit board or test board.

Referring to FIG. 8, the Socketstrate® component or other type of microelectronic assembly may be permanently attached to a printed circuit board 394 by abutting the spheres 386 against the contacts 392 on the printed circuit board 394. In certain preferred embodiments, the attachment process may include providing additional solder 398 to the contacts 392 on the printed circuit board 394. The solder 398 may then be reflowed for forming the attachment. During the reflow operation, the additional solder 398 will wet the surface of the patch of contact metals 404 as well as the sphere 386 and the contact 392 of the printed circuit board 394. Thus, the patch of contact metal 404 may be partially dissolved. In particular, the gold portion of the patch may readily dissolve because it is readably soluble in most molten solders. It is therefore likely that evidence of the original form and location of the contact metal patch 404 will be the remnants of the copper or nickel part of the patch as a piece or a number of pieces distributed through the solidified solder joint. FIG. 8 shows a possible result of soldering the structure shown in FIG. 7B to a printed circuit board. The additional solder from the land 392 of the printed circuit board 394 will wet and partially dissolve the contact metal patch, likely releasing the contact metal patch from the sphere and fragmenting it in the process.

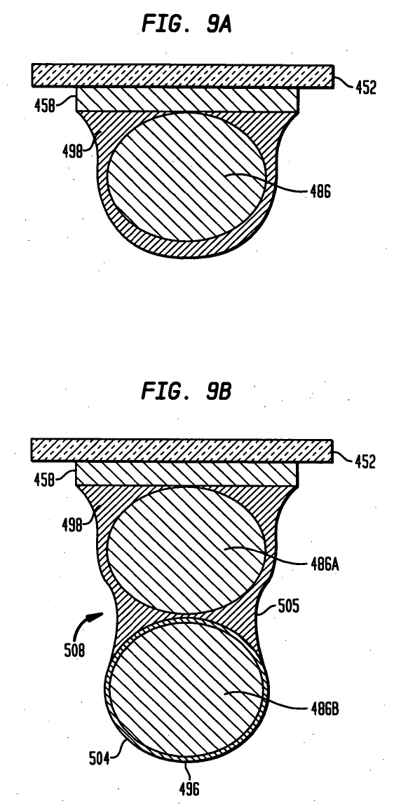

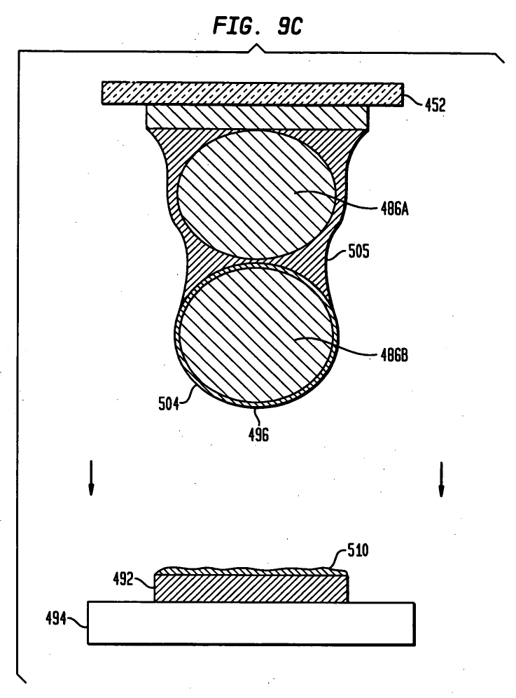

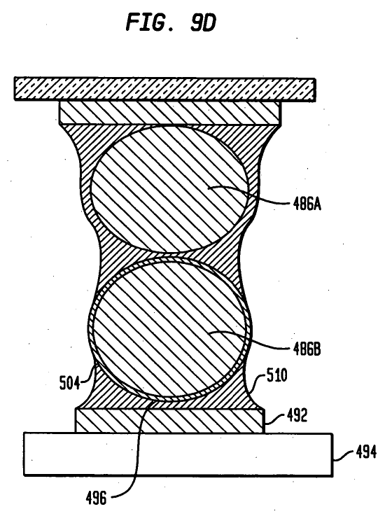

Referring to FIG. 9A, in another preferred embodiment of the present invention, a compliant substrate 452 includes one or more contact pads 458. A first sphere 486 is electrically interconnected with and attached to the contact pad 458 using solder 498. The solder 498 is reflowed and then solidified for attaching the first sphere 486 to the contact pad 458. Surface tension will draw the majority of the solder volume to fill the space where the curvature of the sphere 486 contacts the conductive pad 458.

Referring to FIG. 9B, a second sphere 486B coated with a layer of a contact metal 504 is then placed on top of the first solder coated sphere 486A. A second reflow operation is then conducted which results in just a sufficient amount of solder 505 being drawn to a waist-shaped area 508 between first and second stacked spheres 486A, 486B. Any surplus solder will be preferentially drawn to the waist-shaped region between the spheres by capillary action and will be unlikely to spread over the exposed surface of the second sphere so that the contact area 496 of the second sphere 486B is not contaminated with solder. The solder 505 in the waist-shaped area 508 between the two spheres 486A, 486B facilitates good mechanical and electrical contact between the spheres. The solder 505 present at the waist-shaped area 508, however, is unable to spread over the contact face 496 of the second sphere 486B due to the combined constraints of surface tension and the small volume of solder available. The contact face of the second sphere may comprise a noble metal that does not readily oxidize. In certain preferred embodiments, the contact face of the second sphere may be coated with a noble metal. The second sphere may also have a dielectric core that is coated with a conductive metal layer such as a noble metal layer.

Control of the disposition and spreading of solder in the two-sphere structure shown in FIG. 9B may be accomplished by a number of different techniques including varying the thickness of solder on the first sphere 486A, varying the dimensions of the contact pad 458 to which the first sphere 486A is soldered, and varying the relative diameters of the first and second spheres 486A, 486B. Numerical modeling of wetting and spreading by molten solders as a result of surface tension is a well understood science that can be used to assist in the design of such structures. As will be described in more detail below, the stacked spheres are not required to be the same size. For example, a smaller diameter sphere permits the use of smaller lands on a test board, as well as the printed circuit board to which the microelectronic assembly is finally attached.

Referring to FIG. 9C, the microelectronic assembly having stacked spheres 486A, 486B is juxtaposed with the land bearing face of a printed circuit board 394. In particular preferred embodiments, the contact surfaces 496 of the second spheres 486B are aligned with respective lands 492 on a printed circuit board 494. A mass of solder 510 may be provided on the land 492 of the printed circuit board 494.

Referring to FIG. 9D, the contact surface 496 of the second sphere 486B is abutted against the solder 510 on the land 492, and the solder 510 is reflowed for attaching the second sphere 486B to the land 492. The precious metal coating 504 that was on the contact surface 496 of the second sphere 486B will dissolve in the solder 510 so that the portion of the solder in the vicinity of the printed circuit board land 492 will contain a relatively high concentration of precious metal.

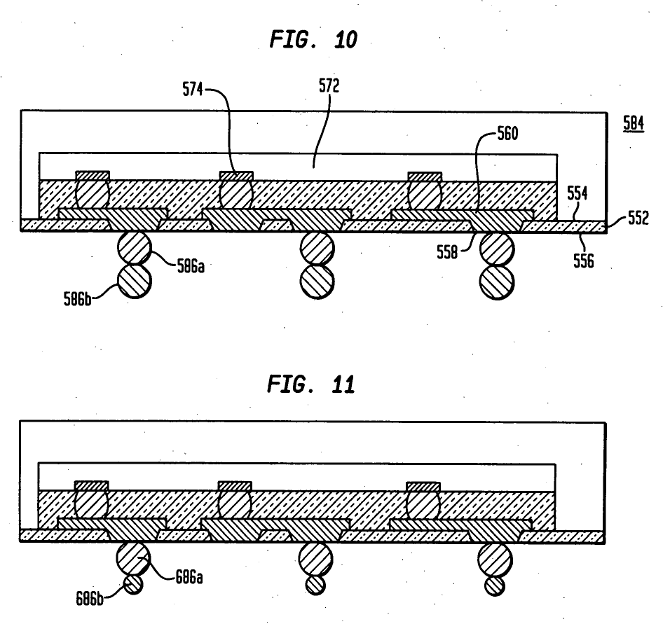

FIG. 10 shows a microelectronic assembly 584 including a microelectronic element 572 having contacts 574. The assembly also includes a flexible, dielectric substrate 552 having conductive pads 558 accessible at a bottom surface 556 thereof. The substrate 552 includes conductive traces 560 that extend over the first surface 554 of the substrate. The assembly also includes conductive support elements 578 that space the substrate 552 from the microelectronic element 572 and electrically interconnect the chip contacts 574 with the traces 560. The assembly also includes first spheres 586A attached to each of the conductive pads 558, and second spheres 586B secured over the first spheres. The stacking of the spheres provides an elongated conductive element that functions like conductive pins or posts for testing the assembly. The first and second spheres have about the same diameters. In certain preferred embodiments, the first sphere is coated with solder and the second sphere has a contact surface that is devoid of solder or other substances that readily oxidize. The contact surface is preferably covered by or made of a noble metal that does not readily oxidize.

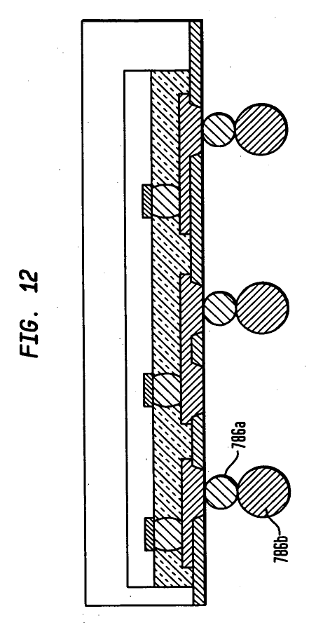

FIG. 11 shows another preferred embodiment of the present invention that is somewhat similar to the assembly of FIG. 10. In the FIG. 11 embodiment, however, the first spheres 686A are larger than the second spheres 686B. The smaller second spheres may be required for connecting with relatively smaller lands. FIG. 12 shows a microelectronic assembly in accordance with another preferred embodiment in which the first spheres 786A are smaller than the second spheres 786B.

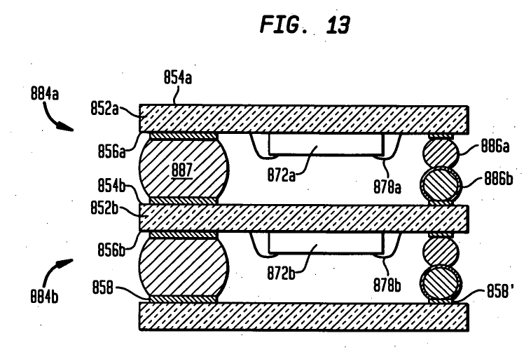

In certain preferred embodiments of the present invention, a stacked structure includes a first package having at least one die that is stacked atop a second package having another die. Referring to FIG. 13, a first microelectronic package 884A includes a flexible, dielectric substrate 852A having a first surface 854A and a second surface 856A remote therefrom. The package includes a semiconductor chip 872A mounted to the second surface 856A and electrically interconnected with the flexible substrate 852A using wire bonds 878A. The first package 884A is stacked atop a second package 884B that includes a flexible, dielectric substrate 852B having a first surface 854B and a second surface 856B remote therefrom. The second package includes a semiconductor chip 872B mounted to the second surface 856B and electrically connected with the flexible substrate 852B using wire bonds 878B. The first and second packages 884A, 884B are then stacked atop one another and electrically interconnected using conductive solder or conductive spheres. As shown in FIG. 13, the left side of the stack uses a single sphere to span the vertical gap between successive layers in the stack. In certain preferred embodiments, however, the size of one or more of the conductive pads may be smaller than other ones of the conductive pads. The area covered by the conductive pad 858 on the left hand side of the second package is larger than the area of the conductive pad 858′ on the right hand side of the package. Thus, on the right hand side of the package, two or more spheres 886A, 886B are stacked on top of one another for spanning the height between the successive layers in the stack, while minimizing the plan area required for electrically interconnecting the two layers. In contrast, a single sphere 887, having a significantly larger footprint, spans the height between the two successive layers of the stack. Although the present invention is not limited by any particular theory of operation, it is believed that a plurality of spheres may be used to span a relatively high gap, when a relatively small footprint is available. The single sphere 887 on the left shows the larger plan area that is required. The stacked spheres 886A, 886B on the right show that the same height may be spanned, while minimizing the plan area required on the flexible substrates 852A, 852B. As a result, a greater number of electrical interconnections may be provided between the successive layers in the stack.

In the particular embodiment shown in FIG. 13, the first sphere 886A is soldered to the conductive pad of substrate 852A. The second sphere 886B having a conductive coating is then attached to the first sphere, however, the contact surface of the second sphere 886B is devoid of solder and is preferably covered by a noble metal or contact metal that does not readily oxidize. As a result, the individual layers in the stack can be readily tested before the stack is assembled together.

Micro Ball Grid Array Placement: Certain preferred embodiments of the present invention will use existing CSP process with existing tape and place the metal balls at the last minute. As follows is a way of making this process work.

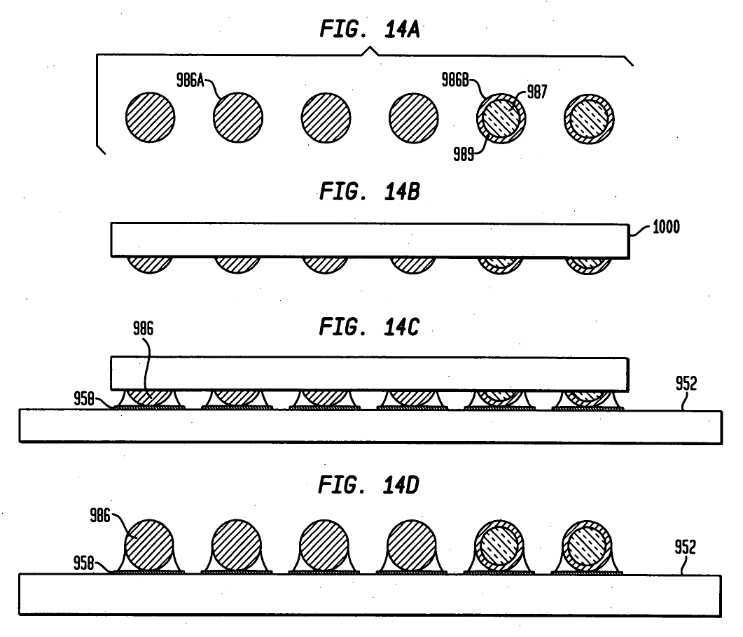

Referring to FIG. 14A, in another preferred embodiment of the present invention, an array of conductive spheres includes first spheres 986A that are solid and second spheres 986B that have non-conductive cores 987 and conductive coatings 989 surrounding the cores. Referring to FIG. 14B, the spheres 986 are held together by a temporary film 1000 such as a water-soluble material. Referring to FIG. 14C, the temporary film 1000 is juxtaposed with a flexible substrate 952 having either a wafer form or a strip form. Referring to FIG. 14C, the spheres 986 are soldered to respective pads 958 on the substrate 952. Referring to FIG. 14D, after the spheres 986 have been attached to the conductive pads 958 of the substrate 952, the temporary film may be removed such as by rinsing in hot water.

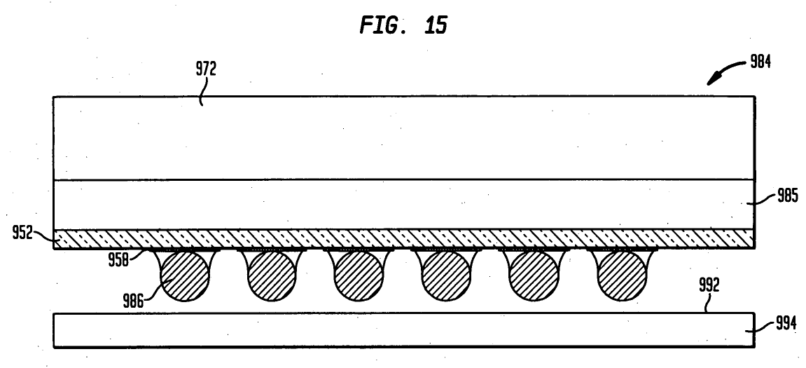

Referring to FIG. 15, the flexible substrate 952 is attached to and electrically interconnected with a microelectronic element 972 such as a semiconductor chip. In The substrate 952 is preferably attached to the microelectronic element 952 in a manner that enables the spheres 986 and conductive pads 958 to move relative to the microelectronic element 952. In certain preferred embodiments, a compliant layer 985 is provided between the substrate 952 and the microelectronic element 952. The microelectronic assembly 984 is then tested or burned-in by juxtaposing the spheres 986 with lands 992 on a test board 994 or printed circuit board. As shown and described in FIG. 4B above, the spheres 986 and substrate 952 are able to move relative to the die 972 to accommodate non-planarity between the spheres 986 and the lands 992 on the test board 994.

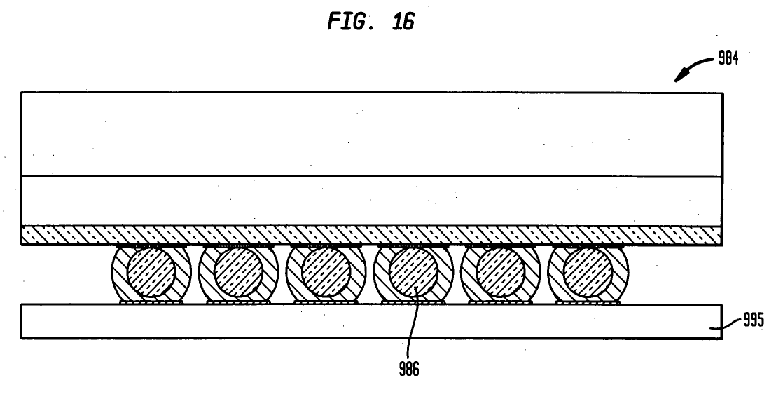

Referring to FIG. 16, the microelectronic assembly 984 may then be connected with a printed circuit board or circuitized element using solder attach. In certain preferred embodiments, the sphere ball is in the middle of the solder attachment after SMT.

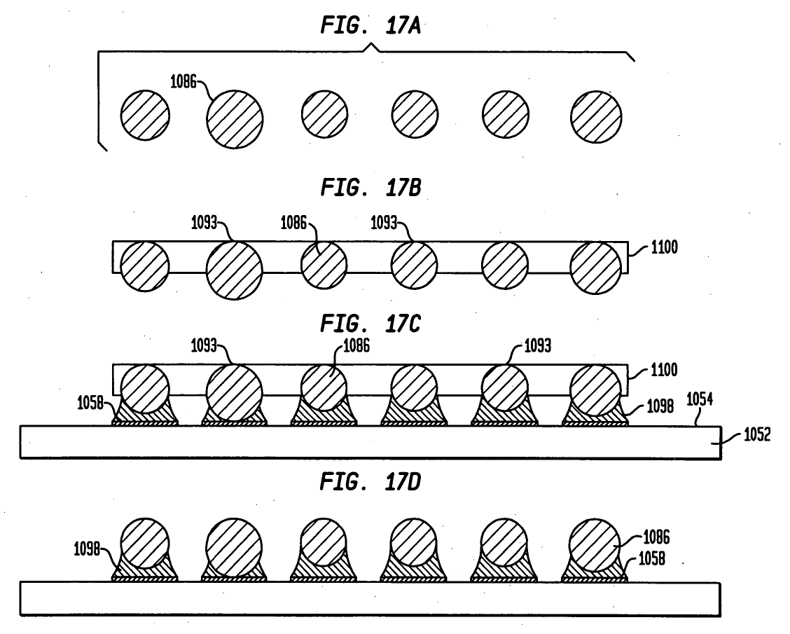

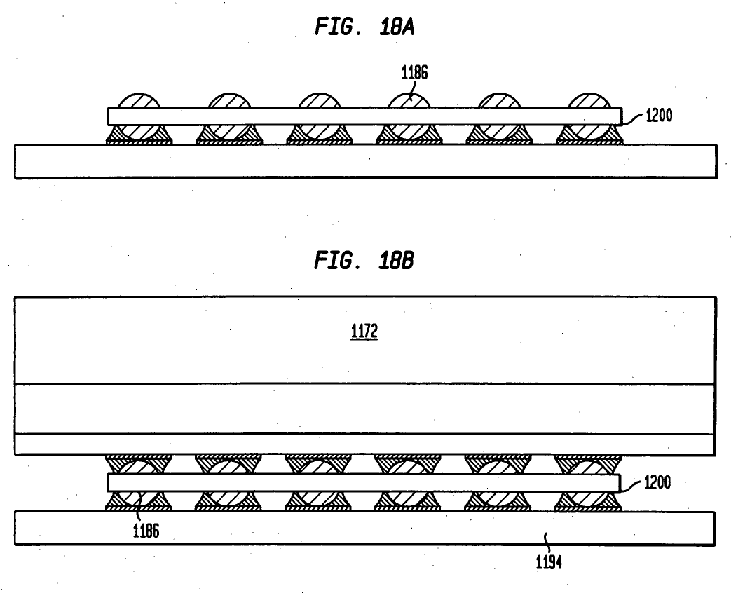

Referring to FIG. 17A, in another preferred embodiment of the present invention, an array of conductive spheres 1086 have different sizes. Referring to FIG. 17B, the spheres 1086 are held together by a temporary film 1100 such as a water-soluble material. The temporary film 1100 aligns the upper ends 1093 of the spheres 1086, in spite of the fact that the spheres have different sizes. Referring to FIG. 17C, the temporary film 1100 is juxtaposed with a flexible substrate 1052 having either a wafer form or a strip form. The flexible substrate includes conductive pads 1058 with solder 1098 provided atop each pad. The spheres 1086 are pushed into the solder pads 1098 so that the height mismatch between the spheres 1086 is absorbed by the solder. As a result, the upper ends 1093 of the spheres 1086 are at the same height H₁ above the first surface 1054 of the substrate 1052. The solder 1098 is reflowed to attach and electrically connect the spheres 1086 with the substrate 1052. Referring to FIG. 17D, after the spheres 1086 have been attached to the conductive pads 1058 of the substrate 1052, the temporary film may be removed such as by rinsing in hot water. Thus, the embodiment of FIGS. 17A-17D provides a method of achieving coplanar spheres, even with different sized spheres. Most of the sphere height mismatch is absorbed in the solder.

FIGS. 18A and 18B show another preferred embodiment that uses a permanent film 1200 for holding the spheres 1186, instead of the temporary film described above. Referring to FIG. 18B, the permanent film 1200 remains in place after the spheres 1186 have been assembled between die 1172 and printed circuit board 1194.

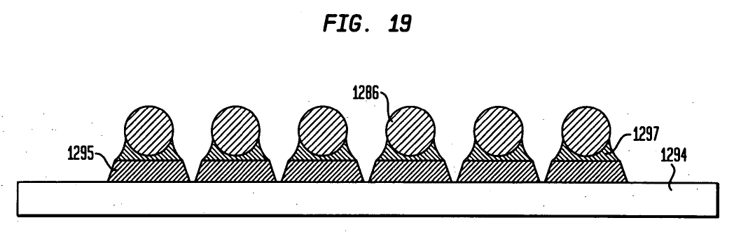

FIG.19 shows a substrate 1294 having compliant bumps 1295. The substrate may be either rigid or compliant. The compliant bumps 1295 have conductive pads 1297 formed thereon that are electrically interconnected with the substrate 1294. Spheres 1286 are electrically interconnected with the conductive pads 1297.

In all of the embodiments described herein, the spheres may be placed on the flexible, dielectric substrate either at before, during or after the packaging process. The attachment mechanism of the spheres to the flexible substrate does not have to be only solder based. Tin, gold or other attachment mechanisms such as brazing and welding are acceptable, as long as the contact surfaces of the spheres are not coated with oxidizable material.

The spheres and rings can be attached to any type of package having one or more microelectronic elements, including compliant packages, rigid packages, stacked packages having two or more layers with vertically arrayed chips and wafer-level packages.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic package comprising:
a microelectronic element having faces and contacts;
a flexible substrate spaced from and overlying a first face of said microelectronic element, said flexible substrate having conductive pads facing away from said first face of said microelectronic element;
a plurality of spheres attached to said conductive pads of said flexible substrate and projecting away from the first face of said microelectronic element, each said sphere having a contact surface remote from said conductive pads, wherein said contact surfaces of said spheres comprise a contact metal devoid of solder; and
a plurality of support elements disposed between said microelectronic element and said substrate for supporting said flexible substrate over said microelectronic element, said spheres being offset from said support elements.

2. The package as claimed in claim 1, wherein each said sphere includes a first sphere that is attached by the solder to one of said conductive pads and a second sphere connected with said first sphere by the solder, said second sphere including said contact surface devoid of the solder.

3. The package as claimed in claim 2, wherein said contact metal comprises a contact metal patch of a noble metal supported by a less noble metal.

4. The package as claimed in claim 3, wherein said noble metal comprises gold and said less noble metal comprises a metal selected from the group consisting of nickel and copper.

5. The package as claimed in claim 2, wherein said second sphere is coated by the solder and the contact surface of said second sphere is covered by a contact metal patch that overlies the solder.

6. The package as claimed in claim 1, wherein said first face is a front face of said microelectronic element and said contacts are accessible at said front face.

7. The package as claimed in claim 6, wherein at least some of said support elements are electrically conductive, at least one of said conductive support elements electrically interconnecting at least one of the contacts of said microelectronic element with at least one of said spheres.

8. The package as claimed in claim 7, wherein said microelectronic element is operable to interchange signals at a frequency above about 300 MHz through at least some of said spheres.

9. The package as claimed in claim 7, wherein said at least one sphere comprises a plurality of spheres, and wherein at least some of said spheres are connected to at least some of said contacts by conductive support elements immediately adjacent to said spheres.

10. The package as claimed in claim 7, further comprising conductive traces provided on said flexible substrate, wherein said conductive traces electrically interconnect at least some of said spheres with at least some of said conductive support elements.

11. The package as claimed in claim 7, wherein said flexible substrate has a bottom surface facing the front face of said microelectronic element and said conductive traces extend along the bottom surface of said flexible substrate.

12. The package as claimed in claim 7, wherein flexible substrate has a top surface facing away from the front face of said microelectronic element and said conductive traces extend along the top surface of said flexible substrate.

13. The package as claimed in claim 7, wherein said contacts are spaced from one another in a grid array over the front face of said microelectronic element.

14. The package as claimed in claim 7, wherein at least one of said conductive support elements comprises a mass of a fusible material.

15. The package as claimed in claim 7, wherein at least one of said conductive elements comprises a dielectric core and an electrically conductive outer coating over the dielectric core.

16. The package as claimed in claim 6, wherein said contacts are disposed in one or more rows extending along the front face of said microelectronic element.

17. The package as claimed in claim 1, wherein said flexible substrate comprises a dielectric sheet.

18. The package as claimed in claim 1, further comprising a compliant material disposed between said flexible substrate and said microelectronic element.

19. The package as claimed in claim 1 wherein said support elements are disposed in an array so that said support elements define a plurality of zones of said flexible substrate, each said zone being bounded by a plurality of said support elements defining corners of said zone, different ones of said spheres being disposed in different ones of said zones.

20. The package as claimed in claim 2Q, wherein only one of said spheres is disposed in each of said zones.

21. A microelectronic assembly comprising a package as claimed in claim 1 and a circuit panel having contact pads, the contact surfaces of said spheres confronting said contact pads and being electrically connected thereto.

22. The assembly as claimed in claim 22 further comprising an electrically conductive bonding material securing said spheres to said contact pads.

23. The assembly as claimed in claim 1, wherein at least one of said spheres comprises a dielectric core and an electrically conductive outer coating over the dielectric core.

24. A microelectronic assembly comprising:
a microelectronic element having faces and contacts;
a flexible substrate spaced from and overlying a first face of said microelectronic element;
a plurality of conductive elements extending from said flexible substrate and projecting away from the first face of said microelectronic element, at least some of said conductive elements being electrically interconnected with said microelectronic element; and
a plurality of support elements disposed between said microelectronic element and said substrate for supporting said flexible substrate over said microelectronic element, at least some of said conductive elements being offset from said support elements, wherein each said conductive element includes a first sphere and a second sphere connected with said first sphere.

25. The assembly as claimed in claim 25, wherein said first sphere is solder coated and said second sphere has a contact surface remote from said first sphere that is devoid of solder.

26. The assembly as claimed in claim 26, wherein the contact surface of said second sphere includes a contact metal.

27. The assembly as claimed in claim 27, wherein said contact metal comprises a noble metal.

28. The assembly as claimed in claim 27, wherein said contact metal comprises a noble metal supported on a less noble metal.

29. The assembly as claimed in claim 29, wherein said noble metal is gold and said less noble metal is selected from the group consisting of nickel and copper.

30. A microelectronic package comprising:
a microelectronic element having a front face with contacts;
a flexible substrate spaced from and overlying said microelectronic element, said flexible substrate having a first surface facing away from the said microelectronic element and a second surface facing said microelectronic element, said flexible substrate being supported above said front face of said microelectronic element so that said substrate is at least partially unconstrained in flexure;
a plurality of conductive elements extending from said flexible substrate and projecting away from said microelectronic element, wherein said conductive elements are electrically connected to said microelectronic element;
each said conductive element comprising at least one sphere having a contact surface that is remote from said flexible substrate, wherein said contact surfaces are covered by a contact metal and are devoid of solder.

31. The package as claimed in claim 30, wherein each said conductive element comprises a first solder coated sphere attached to a conductive pad on said flexible substrate and a second sphere attached to said first sphere, said second sphere including said contact surface covered by said contact metal.
